(19) United States
(12) Patent Application Publication
(10) Pub. No.: US 2024/0395546 A1
(43) Pub. Date: Nov. 28, 2024

(54) METHOD FOR PRODUCING A SEMICONDUCTOR WAFER COMPRISING SILICON AND COMPRISING A III-N LAYER

(71) Applicant: AZUR SPACE Solar Power GmbH, Heilbronn (DE)

(72) Inventors: Atsushi NISHIKAWA, Dresden (DE); Alexander LOESING, Lippstadt (DE)

(73) Assignee: AZUR SPACE Solar Power GmbH, Heilbronn (DE)

(21) Appl. No.: 18/795,048

(22) Filed: Aug. 5, 2024

Related U.S. Application Data
(63) Continuation of application No. PCT/EP2022/000115, filed on Dec. 23, 2022.

(30) Foreign Application Priority Data
Feb. 3, 2022 (DE) 10 2022 000 424.0

(51) Int. Cl. H01L 21/02

(52) U.S. Cl. CPC H01L 21/0254; H01L 21/02381

(57) ABSTRACT

A method for producing a semiconductor wafer comprising silicon and comprising a III-N layer, which has an upper layer region with a top side and a lower layer region with a bottom side. The semiconductor wafer having a total thickness of at least 1.2 mm, and the semiconductor wafer being divided along the total thickness into the upper and lower layer regions. The upper layer region having a peripheral marginal region, and the lower layer region having a second maximum diameter. A connecting region is formed between the upper layer region and the lower layer region. The connecting region having a third diameter, and the third diameter being smaller than the first maximum diameter, comprising producing a nitride layer comprising a III-N layer formed on the upper layer region, and generating a peripheral, edge-filleted or beveled marginal region at the upper layer region.

This nonprovisional application is a continuation of International Application No. PCT/EP2022/000115, which was filed on Dec. 23, 2022, and which claims priority to German Patent Application No. 10 2022 000 424.0, which was filed in Germany on Feb. 3, 2022, and which are both herein incorporated by reference.

### BACKGROUND OF THE INVENTION

### Field of the Invention

The invention relates to a method for producing a semiconductor wafer comprising silicon and comprising a III-N layer.

### Description of the Background Art

Silicon semiconductor wafers comprising an overlying nitride layer are known from DE 10 2006 030 305 and DE 102 569 11. Devices and methods for joining semiconductor wafers and semiconductor wafers comprising an overlying GaN layer are also known from EP 4 012 750 A1 (which corresponds to US 2022/0367188) or WO 2021/024654 A1 or US 2022/367 188 A1, US 2007/069 335 A1, CN 105 814 245 B, and U.S. Pat. No. 6,198,159 B1.

### SUMMARY OF THE INVENTION

It is therefore an object of the invention to provide a device which refines the prior art.

The object is achieved by a method for producing a semiconductor wafer comprising silicon and comprising a III-N layer, which has an upper layer region with a top side and a lower layer region with a bottom side.

The lower layer region comprises a silicon layer or is made up of a silicon layer.

The semiconductor wafer has a total thickness of at least 1.2 mm and is provided with a disk-shaped design. The semiconductor wafer is also divided along the total thickness into the upper layer region and into the lower layer region. The maximum thickness of the semiconductor wafer is 3 mm.

The upper layer region has a peripheral marginal region and a first maximum diameter of at least 145 mm.

The upper layer region has a thickness greater than 30 μm and less than 950 μm. The lower layer region has a second maximum diameter, and a connecting region is formed between the upper layer region and the lower layer region.

The connecting region has a third diameter, the third diameter being smaller than the first maximum diameter.

A peripheral edge-filleted or beveled marginal region is generated at the upper edge region, the marginal region extending along the entire thickness of the upper layer region.

In a method step, a nitride layer can be produced on the upper layer region, the nitride layer comprising a III-N layer.

The lower layer region is processed in such a way that the second maximum diameter corresponds to the first maximum diameter, or the second maximum diameter is designed to be different than the first maximum diameter.

Moreover, the third diameter is smaller than the second maximum diameter or the same size as the second maximum diameter.

It should be noted that the term “III-N” refers to the column of trivalent elements in the periodic system, including, in particular, boron, aluminum, gallium, and indium bonded with nitrogen. In other words, the semiconductor wafer includes not only silicon, but also, in particular in the nitride layer, at least the element nitrogen in a bond with one of the elements in column Ill of the periodic system. In particular, the term “III-N” also comprises layers such as AlGaN or GaN.

A layer comprising or made up of GaN is preferably formed on the top side of the nitride layer.

An advantage of the production method is that, after the nitride layer is produced on the top side of the upper layer region by processing the peripheral marginal region, the semiconductor wafer may be more easily used for a further processing in a semiconductor manufacturing process.

Another advantage of the great thickness of the semiconductor wafer is that the semiconductor wafer, which is made up predominantly of silicon, has no or little tensile or compressive strain during a production of the nitride layer. In other words, the semiconductor wafer made up predominantly of silicon undergoes little or no bending while the nitride is being produced on the top side. In one refinement, the bending of the semiconductor wafer is less than 300 μm or less than 100 μm or less than 30 μm.

A further advantage is that, due to the great thickness of at least 1.2 mm, preferably two silicon semiconductor wafers of typically used thicknesses may be cost-effectively joined to achieve the desired total thickness.

The typically used thicknesses, often also referred to as the SEMI standard, of the semiconductor wafers are listed in Table 1, depending on the diameter of the semiconductor wafer. For comparison, the minimum thickness according to the invention depending on the diameter as well as the typical thicknesses according to the present invention are also listed.

TABLE 1

| | | | | |
|---|---|---|---|---|
| Diameter | 150 mm | 200 mm | 300 mm | >300 mm |
| | | | | (e.g., 450 mm |
| SEMI standard | 625 μm to | 725 μm | 775 μm | ≥775 μm |
| thickness, i.e., | 675 μm | | | (e.g., for a |
| typical thickness | | | | diameter of |
| in the | | | | 450 mm: 925 |
| semiconductor | | | | μm) |
| industry | | | | |
| Minimum | 1.2 mm | 1.2 mm | 1.2 mm | 1.2 mm |
| thickness | | | | |
| according to the | | | | |
| invention | | | | |
| Typical minimum | 1.2 mm | 1.5 mm | >1.5 mm | 1.5 mm to 3 |
| thickness for | | | | mm |
| forming a nitride | | | | |
| layer | | | | |

It is understood that the diameters listed in Table 1 may have a tolerance of usually up to +/−200 μm. It should furthermore be noted that, in an example, the particular tolerances in the case of the diameters may also be designed to be larger or smaller. It should also be noted that, in another refinement, the semiconductor wafers also have other diameters, the minimum thickness in the case of all diameters, however, being greater than 1.0 mm.

The upper layer region can comprise a silicon layer or is made up of a silicon layer, the nitride layer resting upon the silicon layer and forming the top side of the semiconductor wafer. In an example, the upper layer region comprises a silicon semiconductor wafer according to the SEMI standard thickness.

The thickness of the upper layer region can be between 100 μm and 900 μm or between 500 μm and 800 μm.

The silicon layer of the upper layer region can have a thickness D1 between 30 μm and 950 μm or between 100 μm and 900 μm or between 500 μm and 800 μm.

The thickness D2 of lower layer region USB can be greater than 10 μm and less than 950 μm.

The semiconductor wafer can be made up of more than 40% or more than 60% or more than 80% and no more than 90% or no more than 98% or no more than 99% silicon.

The semiconductor wafer can be obtained in its entire thickness from an ingot by means of a sawing step or in another way, so that the semiconductor wafer is monolithic along its total thickness, i.e., it is designed as a single piece. The diameter of the semiconductor wafer is subsequently reduced within the transitional region, so that the third diameter is smaller than the first diameter.

The semiconductor wafer can have a connecting surface in the connecting region, i.e., in the region between the upper layer region and the lower layer region. In other words, the semiconductor wafer has a two-piece design. It is joined at the connecting surface. It is understood that available aids such as adhesive or metal layers or a combination of multiple materials are comprised.

A semiconductor bond can be formed at the connecting surface. It should be noted that the term semiconductor bond is used synonymously with the term wafer bond. In an example, the upper region is joined directly to the lower region in a materially bonded manner, preferably without forming intermediate layers. Intermediate layers in this case are understood to be layers which have a different chemical composition than the chemical composition of the two semiconductor layers which are joined.

The semiconductor bond can be carried out using a silicon dioxide layer, the silicon dioxide layer having a thickness between a monolayer and a thickness of less than 10 μm or less than 1 μm or less than 100 nm. In other words, the silicon dioxide layer forms an intermediate layer between the upper layer region and the lower layer region.

In an example, after the process steps of generating the marginal region and processing the lower layer region, the first maximum diameter deviates from the second maximum diameter by no more than 10 mm or no more than 2 mm, or the first diameter corresponds to the second diameter, or the two diameters are of the same size.

In an example, after the process steps of generating the marginal region and processing the lower layer region, the second maximum diameter is designed to be no more than 5 mm smaller or no more than 2 mm larger than the first maximum diameter.

In an example, the first maximum diameter is of the same size as the second maximum diameter, or the first maximum diameter is designed to be equal to the second maximum diameter.

In an example, the peripheral marginal region of the upper layer region is designed to be angular or not angular. In an example, the peripheral marginal region of the upper layer region is rounded, or the peripheral marginal region of the upper layer region is designed according to the JEITA standard or the SEMI standard.

In an example, a peripheral, rounded marginal region is formed at the lower layer region. In an example, an increasing diameter and/or decreasing diameter along thickness D2 of the semiconductor wafer is formed at the lower layer region.

In an example, the nitride layer comprises one or multiple III-N and/or metal nitride layers. In particular, single or multiple layers comprising or made up of AlGaN, GaN, AlN, InN, and TIN are formed in the nitride layer.

In an example, multiple nitride layers are formed.

In an example, the nitride layer is generated with a thickness of at least 1 μm or at least 4 μm and a thickness of no more than 30 μm. In an example, the GaN layer is produced on the top side of the upper layer region with a thickness of between 0.5 μm and 10 μm or between 1.0 μm and 5 μm.

In an example, a right-angled edge is not generated at the upper peripheral marginal region. In one refinement, the upper peripheral marginal region and the lower peripheral marginal region are each edge-filleted.

In an example, a layer comprising or made up of GaN is formed on the top side of the nitride layer.

It should be noted that total thickness GD is designed as a sum of thickness D1 of the upper layer region and thickness D2 of the lower layer region and thickness D3 of the nitride layer.

In an example, the generation of the marginal region at the upper layer region is carried out before or after the production of the nitride layer.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a view of an example of a semiconductor wafer generated according to the production method, which comprises silicon and comprises a III-N layer;

FIG. 2 shows a view of an example of a semiconductor wafer generated according to the production method, which comprises silicon and comprises a III-N layer;

FIG. 3 shows a view of an example of a semiconductor wafer generated according to the production method, which comprises silicon and comprises a III-N layer;

FIG. 4 shows a view of an example of a semiconductor wafer generated according to the production method, which comprises silicon and comprises a III-N layer; and

FIG. 5 shows a sequence of multiple manufacturing steps, referenced by I through IV, for producing a semiconductor wafer comprising silicon and comprising a III-N layer.

### DETAILED DESCRIPTION

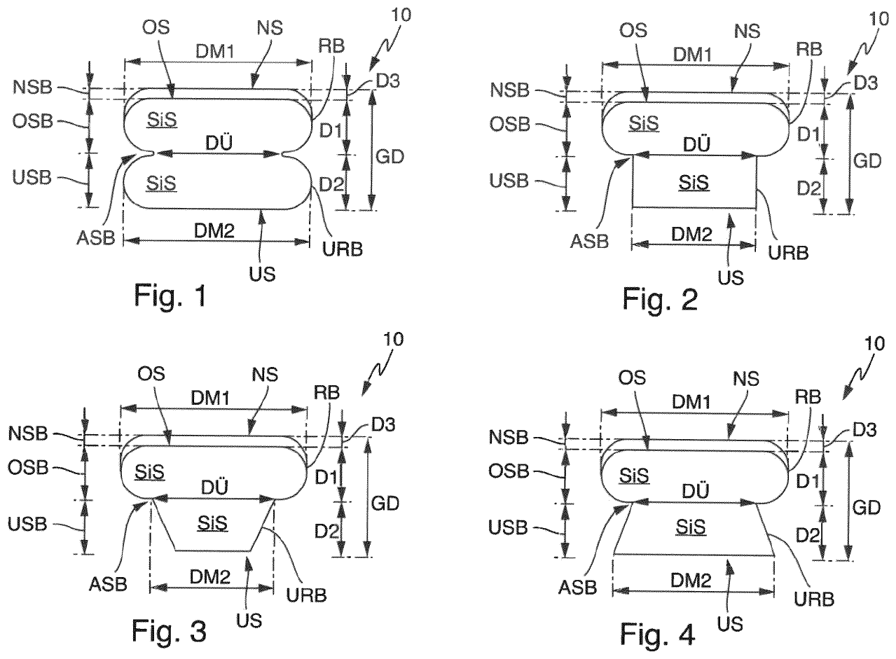

The illustration in FIG. 1 shows an example, including a semiconductor wafer generated according to the production method, which comprises silicon and comprises a III-N wafer having an upper layer region OSB with a top side OS and a thickness D1 and having a lower layer region USB with a thickness D2 and a bottom side US, a nitride layer NSB having a thickness D3 being formed on upper side OS of upper layer region OSB.

Upper layer OSB is made up of a silicon layer SIS, nitride layer NSB resting upon silicon layer SIS and forming top side NS. Silicon layer SIS of upper layer region OSB is between 100 μm and 950 μm.

Nitride layer NSB comprises at least one III-N and/or metal nitride layer.

In the illustrated example, a thin III-N layer is formed on surface NS of nitride layer NSB. The III-N layer preferably comprises or is made up of GaN.

It is understood that, in an example which is not illustrated, the III-N layer is additionally or alternatively formed at different location of nitride layer NSB.

Nitride layer NSB has a thickness of at least 1 μm or at least 4 μm and a thickness of no more than 30 μm.

Thickness D1 of upper layer region OSB is less than 950 μm. Thickness D2 of lower layer region USB is greater than 10 μm and less than 950 μm.

Lower layer region USB comprises or is made up of a silicon layer SIS.

Semiconductor wafer 10 has a total thickness GD of at least 1.2 mm and is provided with a disk-shaped design. The maximum thickness of semiconductor wafer 10 is 3 mm.

As discussed above, semiconductor wafer 10 is divided along total thickness GD into upper layer region OSB and into lower layer region USB. Upper layer region OSB has a peripheral marginal region RB, upper marginal region RB not having a right-angled edge but rather a rounded edge. Upper layer region OSB furthermore has a first maximum diameter DM1 of at least 145 mm.

Lower layer region USB has a second maximum diameter DM2, lower marginal region URB not having a right-angled edge but rather a rounded edge. A connecting region ASB is formed between upper layer region OSB and lower layer region USB, connecting region ASB having a third diameter DÜ. First maximum diameter DM1 corresponds to second maximum diameter DM2.

Third diameter DU is designed to be smaller than first maximum diameter DM1 and smaller than second maximum diameter DM2.

A semiconductor bond is formed at connecting region ASB between upper layer region OSB and lower layer region USB.

First maximum diameter DM1 deviates from second maximum diameter DM2 by no more than 2 mm. Peripheral marginal region RB of upper layer region OSB is preferably provided with a rounded design or is designed to have a shape according to the JEITA standard or the SEMI standard.

Lower layer region USB has a peripheral, rounded marginal region URB. Lower layer region USB is made up of silicon, an oxide layer being formed on bottom side US in an example.

The illustration in FIG. 2 shows an example of a semiconductor wafer generated according to the production method, which comprises silicon and comprises a III-N layer. Only the differences from the illustration in FIG. 1 are explained below.

Lower layer region USB has a constant diameter DM2 along thickness D2, starting from connecting region ASB in the direction of bottom side US.

The illustration in FIG. 3 shows an example of a semiconductor wafer generated according to the production method, which comprises silicon and comprises a III-N layer. Only the differences from the illustration in FIG. 1 are explained below.

Lower layer region USB has a decreasing diameter DM2 along thickness D2, starting from connecting region ASB in the direction of bottom side US.

The illustration in FIG. 4 shows an example of a semiconductor wafer generated according to the production method, which comprises silicon and comprises a III-N layer. Only the differences from the illustration in FIG. 1 are explained below.

Lower layer region USB has an increasing diameter DM2 along thickness D2, starting from connecting region ASB in the direction of bottom side US.

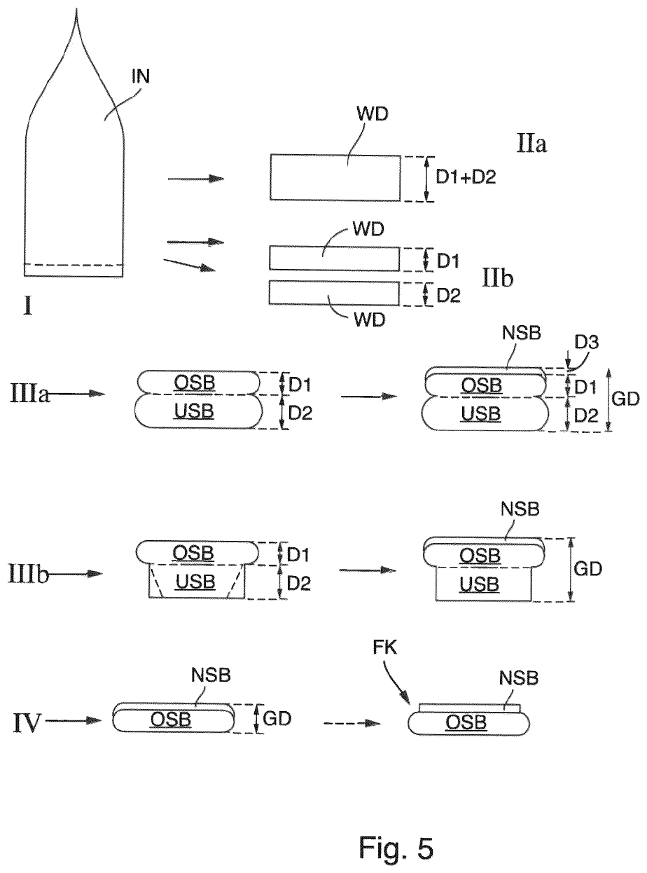

The illustration in FIG. 5 shows a sequence of multiple manufacturing steps, referenced by I through IV, for generating a thick semiconductor wafer according to the production method, which comprises silicon and comprises a III-N layer. Only the differences from the illustration in FIG. 1 are explained below.

A thick semiconductor wafer WD having a thickness of at least 1.2 mm is sawed from an ingot IN, illustrated in first step I, or separated therefrom in another way, as illustrated in step 11a. It is understood that further steps, in particular polishing steps, are carried out after the sawing or separation. In an alternative step, illustrated in step IIb, two individual semiconductor wafers WD are obtained, which have a thickness of D1 and a thickness of D2.

The further steps IIIa, IIIb are explained below, which have two individual semiconductor wafers joined to form one thick semiconductor wafer 10.

In step IIIa, round peripheral edge RB is produced at upper layer region OSB, and round peripheral edge URB is produced at lower layer region USB. Nitride layer NSB is then generated on upper layer region OSB.

In step IIIb, round peripheral edge RB is generated only at upper layer region OSB. Either a constant diameter or a decreasing diameter along thickness D2 is generated at lower layer region USB. Nitride layer NSB is then generated on upper layer region OSB.

In a subsequent step IV, lower layer region USB is removed and, in a final step, nitride layer NSB is removed at an edge region FK on the top side of upper layer region OSN by means of etching and/or by means of grinding or using a different method.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A production method for a semiconductor wafer comprising silicon and comprising a III-N layer, having an upper layer region with a top side and having a lower layer region with a bottom side, the lower layer region comprising a silicon layer or being made up of a silicon layer, and the semiconductor wafer having a total thickness of at least 1.2 mm and being provided with a disk-shaped design, the semiconductor wafer being divided along the total thickness into the upper layer region and into the lower layer region, the upper layer region having a peripheral marginal region, the upper layer region having a first maximum diameter of at least 145 mm, the upper layer region having a thickness greater than 30 μm and less than 950 μm, the lower layer region having a second maximum diameter, the method comprising:
forming a connecting region between the upper layer region and the lower layer region;
forming a nitride layer comprising a III-N layer on the upper layer region being produced;
producing a peripheral, edge-filleted or beveled marginal region at the upper layer region, the marginal region extending along an entire thickness of the upper layer region;
processing the lower layer region such that the second maximum diameter corresponds to the first maximum diameter or the second maximum diameter is different than the first maximum diameter;
forming a peripheral, rounded marginal region at the lower layer region;
forming a third diameter at the connecting region, the third diameter being smaller than the first maximum diameter and the third diameter being smaller than the second maximum diameter or is the same size as the second maximum diameter; and
obtaining the semiconductor wafer, which has a total thickness, from an ingot via a sawing or separating step so that the semiconductor wafer is formed monolithically along the total thickness or so that the semiconductor wafer has a connecting surface comprising a semiconductor bond formed in the connecting region, the semiconductor bond being designed without the formation of intermediate layers or comprising a silicon dioxide layer.

2. The production method according to claim 1, wherein the silicon dioxide layer has a thickness between a monolayer and a thickness of less than 10 μm or less than 1 μm or less than 100 nm.

3. The production method according to claim 1, wherein the semiconductor wafer is made up of more than 40% or more than 60% or more than 80%, but a maximum of 99%, silicon.

4. The production method according to claim 1, wherein, after the process steps of generating the marginal region and processing the lower layer region, the first maximum diameter deviates from the second maximum diameter by no more than 10 mm, or the first maximum diameter corresponds to the second maximum diameter, or the two diameters are of the same size.

5. The production method according to claim 1, wherein, after the process steps of generating the marginal region and processing the lower layer region, the second maximum diameter is no more than 5 mm smaller or no more than 2 mm larger than the first maximum diameter.

6. The production method according to claim 1, wherein the peripheral marginal region of the upper layer region is designed to be angular or not angular, or the peripheral marginal region of the upper layer region is designed to be rounded, or the peripheral marginal region of the upper layer region is designed according to the JEITA standard or the SEMI standard.

7. The production method according to claim 1, wherein an increasing diameter and/or decreasing diameter along a thickness of the lower layer region is formed at the lower layer region.

8. The production method according to claim 1, wherein at least one or multiple III-N layer(s) and/or one or multiple metal nitride layer(s) is/are produced during the production of the nitride layer.

9. The production method according to claim 1, wherein the nitride layer is formed with a thickness of at least 1 μm or at least 4 μm and a thickness of no more than 30 μm.

10. The production method according to claim 1, wherein the upper peripheral marginal region is shaped in such a way that no right-angled edge forms.

11. The production method according to claim 1, wherein the upper layer region comprises a silicon layer or is made up of a silicon layer and has a thickness between 100 μm and 900 μm or between 500 μm and 800 μm.

12. The production method according to claim 1, wherein the generation of the marginal region at the upper layer region is carried out before or after the production of the nitride layer.
